(19) United States
(12) Patent Application Publication
(10) Pub. No.: US 2022/0166190 A1
(43) Pub. Date: May 26, 2022

(54) HIGH-POWER SEMICONDUCTOR CHIP AND PREPARATION METHOD THEREFOR

(71) Applicant: Everbright Institute of Semiconductor Photonics Co.,Ltd., Suzhou,Jiangsu (CN)

(72) Inventors: Shaoyang Tan, Suzhou, Jiangsu (CN); Jun Wang, Suzhou, Jiangsu (CN); Hong Xu, Suzhou, Jiangsu (CN); Dayong Min, Suzhou, Jiangsu (CN)

(21) Appl. No.: 17/426,463

(22) PCT Filed: Oct. 12, 2019
(86) PCT No.: PCT/CN2019/110897

§ 371 Date: Jul. 28, 2021

(30) Foreign Application Priority Data
May 13, 2019 (CN) 201910395812.3

(51) Int. Cl. H01S 5/12; H01S 5/028

(52) U.S. Cl. CPC H01S 5/1237; H01S 5/1231; H01S 5/028

(57) ABSTRACT

A high-power semiconductor chip and a preparation method therefor. The semiconductor chip comprises: a substrate (1), a lower confinement layer (2), a lower waveguide layer (3), an active layer (4), an upper waveguide layer (5), a lateral grating layer (10), an upper confinement layer (6), a contact layer (7), a current isolation dielectric layer (8) and a metal layer (9), sequentially arranged from bottom to top, wherein the lateral grating layer (10) comprises a plurality of groups of lateral gratings; the plurality of groups of lateral gratings are sequentially arranged in a first direction; the periods of the plurality of groups of lateral gratings are different from each other; each group of lateral gratings comprises a plurality of gratings; the plurality of gratings are arranged in a second direction; and the first direction intersects with the second direction. Providing a lateral grating layer (10) in a waveguide improves the propagation loss of the high-order lateral light mode in the waveguide, and achieves the aim of suppressing the lasing of the high-order lateral light mode; and providing a plurality of groups of gratings with different periods suppresses the lasing of an intensity oscillation light mode caused by single grating gain modulation and refractive index modulation, achieves the effect of suppressing lateral light intensity periodic oscillation and eliminates the formation of far-field double humps.

### TECHNICAL FIELD

The present application relates to the field of semiconductor photoelectrons, in particular to a high-power semiconductor chip and a preparation method thereof.

### BACKGROUND ART

The development direction of high-power semiconductor laser chip is higher light power of output light and higher brightness. Increasing the width of the light-emitting region of the laser chip and preparing a wide waveguide semiconductor laser chip are effective means to increase the light power, for example, the power of semiconductor laser chip with a waveguide width of about 100-200 microns can reach over 10 W. However, the increase in the width of the light-emitting region brings a problem that when the chip operates, dozens of or even more high-order lateral light modes are excited at the same time, resulting in an increased divergence angle. In the method that has been used now to suppress the excitation of high-order lateral light modes, a multi-grating structure or multiple electrodes or waveguide stripes are introduced inside the wide waveguide, and the high-order mode light limiting factor of the introduced light scattering structure is large enough, however, this method will lead to a strong periodic distribution of light gain and wide-field lateralization, thereby triggering the problem of multiple humps in the far field.

### SUMMARY OF THE INVENTION

In view of this, embodiments of the present application provide a high-power semiconductor chip and a preparation method thereof, to solve the problem of triggering far-field multiple humps in the controlled suppression of lateral mode excitation of higher-order light.

According to a first aspect, embodiments of the present application provide a high-power semiconductor chip, including: a substrate, a lower confinement layer, a lower waveguide layer, an active layer, an upper waveguide layer, a lateral grating layer, an upper confinement layer, a contact layer, a current isolation dielectric layer and a metal layer which are sequentially arranged from bottom to top, wherein the lateral grating layer includes a plurality of groups of lateral gratings; the plurality of groups of lateral gratings are sequentially arranged along a first direction; the periods of the plurality of groups of lateral gratings are different from each other; each group of lateral gratings includes a plurality of gratings; the plurality of gratings are arranged along a second direction; and the first direction intersects with the second direction.

Optionally, the first direction is a light radiation direction.

Optionally, the first direction is vertical to the second direction.

Optionally, the periods of each group of lateral gratings are distributed progressively or randomly in the first direction.

Optionally, the current isolation dielectric layer and the metal layer are defined to form a current injection region, and the lateral grating layer is arranged in the current injection region.

Optionally, an anti-reflection coating layer is arranged on a light-exiting end face of the semiconductor chip, and a high-reflection coating layer is arranged on a high-reflection end face.

Optionally, the periods of the plurality of groups of lateral gratings are respectively as follows: dᵢ=2w/(m+i); wherein dᵢ is the period, w is the width of the upper waveguide layer, m is the light mode order, and i is an integer greater than or equal to 1.

According to a second aspect, embodiments of the present application provide a preparation method of a high-power semiconductor chip, including: forming in sequence a lower confinement layer, a lower waveguide layer, an active layer, and an upper waveguide layer on the substrate; forming in sequence a plurality of groups of lateral gratings on the upper waveguide layer along the first direction, wherein the periods of the plurality of groups of lateral gratings are different from each other, a plurality of gratings of each group of lateral gratings are distributed along the second direction, and the first direction intersects with the second direction; and forming in sequence an upper confinement layer, a contact layer, a current isolation dielectric layer and a metal layer on the plurality of groups of lateral gratings.

Optionally, the forming in sequence a plurality of groups of lateral gratings on the upper waveguide layer along the first direction includes: forming a lateral grating layer on the upper waveguide layer through epitaxial growth; and etching on the lateral grating layer to form grating stripes.

In the high-power semiconductor chip provided in the embodiments of the present application, a lateral grating layer is arranged inside the waveguide, so that the suppression effect of higher-order light modes will not be limited by the width of the chip waveguide, and the high-order lateral light modes can have sufficient overlap with the grating structure, so that the high-order lateral light mode is subject to the diffraction effect of light in the non-horizontal plane, which introduces the propagation loss of high-order lateral light mode inside the waveguide, and can suppress the excitation of the high-order lateral light mode and improve the power of the semiconductor chip; at the same time, multiple groups of gratings with different periods are set, so that the light with periodically oscillated intensity caused by gain modulation and refractive index modulation cannot keep matching with the period of the grating in the first direction, thereby achieving the effect of suppressing its excitation, achieving the effect of suppressing the lateral light intensity periodic oscillation, and eliminating the far-field double humps.

### BRIEF DESCRIPTION OF THE DRAWINGS

In order to more clearly illustrate the technical solutions in the specific embodiments or the prior art of the present application, a brief introduction will be given below on the accompanying drawings that need to be used in the description of the specific embodiments or the prior art. Obviously, the accompanying drawings in the following description are some of the embodiments of the present application, and for those of ordinary skills in the art, other drawings can be obtained based on these accompanying drawings without any creative work.

FIG. 1 shows a schematic diagram of a section plane in a second direction of the structure of the semiconductor chip in an embodiment of the present application.

FIG. 2 shows a three-dimensional structural schematic diagram of the semiconductor chip of the embodiment of the present application.

Wherein, 1 represents a substrate, 2 represents a lower confinement layer, 3 represents a lower waveguide layer, 4 represents an active layer, 5 represents an upper waveguide layer, 6 represents an upper confinement layer, 7 represents a contact layer, 8 represents a current isolation dielectric layer, 9 represents a metal layer, and 10 represents a lateral grating layer.

### DETAILED DESCRIPTION OF THE EMBODIMENTS

In order to make the objectives, technical solutions and advantages of the embodiments of the present application clearer, the technical solutions in the embodiments of the present application will be described clearly and completely below in combination with the accompanying drawings in the embodiments of the present application. Obviously, the embodiments described are a part but not all of the embodiments of the present application. Based on the embodiments in the present application, all the other embodiments obtained by those skilled in the art without any creative effort shall fall within the protection scope of the present application.

The present application may be implemented in many different forms and should not be construed as being limited to the embodiments set forth herein. On the contrary, these embodiments are provided so that the present disclosure will be thorough and complete and will fully communicate the concepts of the present application to those skilled in the art, and the present application will be limited only by the claims. In the accompanying drawings, the dimensions and relative dimensions of the layers and regions will be exaggerated for clarity.

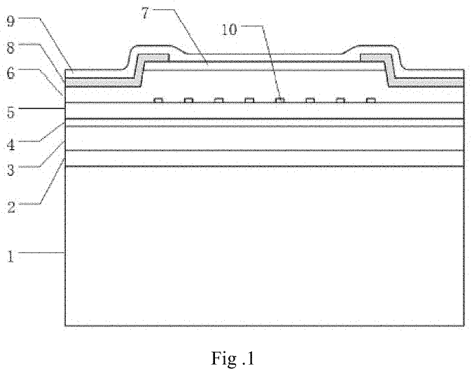

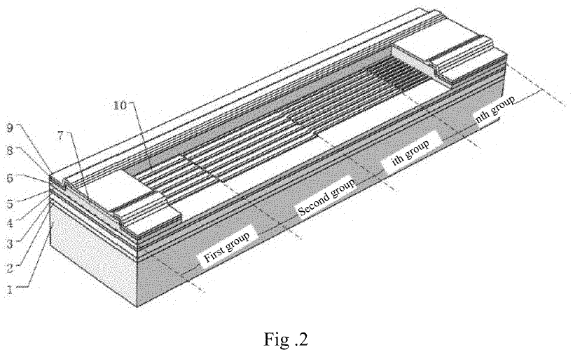

Embodiments of the present application provide a high-power semiconductor chip, as shown in FIGS. 1-2, including: a substrate 1, a lower confinement layer 2, a lower waveguide layer 3, an active layer 4, an upper waveguide layer 5, a lateral grating layer 10, an upper confinement layer 6, a contact layer 7, a current isolation medium layer 8, and a metal layer 9 arranged in sequence from bottom to top; wherein the lateral grating layer 10 includes a plurality of groups of lateral gratings, the plurality of groups of lateral gratings are arranged in sequence along the first direction, the periods of the plurality of groups of lateral gratings vary, each group of lateral gratings includes a plurality of gratings, the plurality of gratings are arranged along the second direction, and the first direction intersects with the second direction. In the embodiment of the present application, the structure of the active layer 4 can be one of a double heterogeneous structure, a single and double quantum well structure, or a multiple quantum well structure. The material of the substrate 1 can be GaAs, and the lower layer of the substrate 1 can also include an electrode layer, and the material of the electrode layer can be a metal or an alloy.

In the high-power semiconductor chip provided in the embodiments of the present application, a lateral grating layer is arranged inside the waveguide, so that the suppression effect of higher-order light modes will not be limited by the width of the chip waveguide, and the high-order lateral light modes can have sufficient overlap with the grating structure, so that the high-order lateral light mode is subject to the diffraction effect of light in the non-horizontal plane, which introduces the propagation loss of high-order lateral light modes inside the waveguide, and can suppress the excitation of the high-order lateral light mode and improve the power of the semiconductor chip; at the same time, multiple groups of gratings with different periods are set, so that the light with periodically oscillated intensity caused by gain modulation and refractive index modulation cannot keep matching with the period of the grating in the first direction, thereby achieving the effect of suppressing its excitation, achieving the effect of suppressing the lateral light intensity periodic oscillation, and eliminating the far-field double humps.

In an optional embodiment, the first direction is the light radiation direction. In the embodiment of the present application, the first direction is the longitudinal direction of the semiconductor chip, and the light radiation direction is also the longitudinal direction of the semiconductor chip, and the first direction is the light radiation direction.

In an optional embodiment, the first direction is vertical to the second direction. In the embodiment of the present application, the second direction is the side direction of the semiconductor chip, the first direction is the longitudinal direction of the semiconductor chip, and the first direction is vertical to the second direction.

In an optional embodiment, the current isolation dielectric layer 8 and the metal layer 9 are defined to form a current injection region, and the lateral grating layer 10 is arranged in the current injection region. In the embodiment of the present application, a current injection region is formed between the current isolation dielectric layer 8 and the upper waveguide layer 5, and the current injection region is defined by the current isolation dielectric layer 8 and the metal layer 9, and the current injection region is ridge-shaped, and the lateral grating layer 10 is arranged in the current injection region. This design not only increases the contact area of current, but also improves the instability of the lateral mode due to the wide ridge-shaped table in the high-order lateral light mode, and suppresses the excitation of the high-order lateral light mode.

In an optional embodiment, the light emitting end face of the semiconductor chip is provided with an anti-reflective coating layer, and the highly reflective end face is provided with a highly reflective coating layer. In the embodiment of the present application, in order to improve the light emitting proportion of one cavity surface of the two cavity surfaces of the semiconductor chip, a low-reflectivity anti-reflective coating can be arranged on the light emitting end face, and a high-reflectivity high-reflective coating can be arranged on the other end face, i.e., the high-reflectivity end face.

In an optional embodiment, the period of each group of lateral gratings is arranged progressively or randomly in the first direction; the period of the multiple groups of lateral gratings are as follows: dᵢ=2w/(m+i); wherein dᵢ is the period, w is the width of the upper waveguide layer, m is the light mode order, and i is an integer greater than or equal to 1. In the embodiment of the present application, the period of each group of lateral gratings varies, and when the period of each group of lateral gratings is arranged progressively in the first direction, the period of each group of gratings can be 2w/(m+1), 2w/(m+2), 2w/(m+3) . . . , respectively along the first direction, when the period of each group of lateral gratings is arranged randomly in the first direction, the periods can be arranged in sequence in the order of magnitude of the period or not in the order of magnitude of the grating period, and can be specifically set according to the actual needs.

For ease of understanding, specifically, the present application is explained in terms of a preferred embodiment of the present application, i.e., a uniformly periodic grating structure. In the embodiment of the present application, the grating has a period of d in the lateral direction, the optical waveguide width is w, and the effective refractive index of the optical waveguide is N. In order to suppress the light excitation of the m-order lateral mode, a grating structure is set on the upper waveguide layer, and the period of the grating is designed as d=2w/(m+1), so that the high-order lateral light modes above the m-order are all subject to the diffraction effect of light on the non-horizontal plane, which increases the light propagation loss of the m-order lateral mode, and suppresses the excitation of the m-order lateral light mode, thereby improving the power of the semiconductor chip, but at the same time, due to gain modulation and refractive index modulation, light oscillation of (m−1)/2 order lateral mode is caused, thereby resulting in far-field double humps, therefore, in the embodiment of the present application, in the direction of light radiation (longitudinal direction), multiple groups (≥2) of gratings of different periods are introduced to suppress the light oscillation of (m−1)/2 order lateral mode due to gain modulation and refractive index modulation. Since the light of the (m−1)/2 order lateral mode does not match with the period of the other groups of gratings, the light cannot be gained, thereby achieving the effect of suppressing its excitation, achieving the effect of suppressing the periodic oscillation of the lateral light intensity and eliminating the far-field double humps. The period of each group of optional gratings is as follows: d′=2w/(m′+1), wherein m′=m+1, m+2, . . . .

Embodiments of the present application provide a preparation method of a high-power semiconductor chip, including: forming in sequence a lower confinement layer, a lower waveguide layer, an active layer, and an upper waveguide layer on the substrate in sequence; forming in sequence a plurality of groups of lateral gratings on the upper waveguide layer along the first direction, wherein the periods of the plurality of groups of lateral gratings are different from each other, a plurality of gratings of each group of lateral gratings are distributed along the second direction, and the first direction intersects with the second direction; and forming in sequence an upper confinement layer, a contact layer, a current isolation dielectric layer and a metal layer on the plurality of groups of lateral gratings. The manufacturing of semiconductor lasers has relatively mature process conditions and processes. The design of the present application is an improvement based on the ordinary high-power lasers, and the process technology can be guaranteed, and the process is relatively less complicated. Therefore, the design is suitable for production. In the embodiment of the present application, the specific process of the semiconductor chip can include: providing a substrate, wherein the material of the substrate can be GaAs, and using a metal-organic chemical vapor deposition (MOCVD) method to extend a lower confinement layer, a lower waveguide layer, an active layer and an upper waveguide layer in sequence on the GaAs substrate. A lateral grating layer is formed on the upper waveguide layer through epitaxial growth, the relevant parameters (such as period, proportion, material) of the lateral grating are set, and photolithography is used to lithograph each group of grating stripes in the lateral grating layer, since the period of the lateral grating is still relatively long, photolithography can be directly used, and the equipment for lithography is a contact exposure lithography machine. Then an upper confinement layer and a contact layer are formed in sequence on the lateral grating layer through epitaxial growth. A current injection ridge-shaped table is formed on the upper contact layer, the upper confinement layer and the upper waveguide layer through lithography and dry or wet etching. The current isolation dielectric layer is deposited, the current isolation dielectric layer is removed at the top of the ridge-shaped table to form a current injection window, and finally the upper metal layer is deposited. In other embodiments, the lower confinement layer, the lower waveguide layer, the active layer, and the upper waveguide layer can also be formed sequentially on the substrate through epitaxial growth.

In an optional embodiment, each group of grating stripes may be formed on the upper waveguide layer through etching grooves.

Although embodiments of the present application are described in combination with the accompanying drawings, various modifications and variations may be made by those skilled in the art without departing from the spirit and scope of the present application, and such modifications and variations shall all fall within the scope defined by the appended claims.

1. A high-power semiconductor chip, comprising:
a substrate, a lower confinement layer, a lower waveguide layer, an active layer, an upper waveguide layer, a lateral grating layer, an upper confinement layer, a contact layer, a current isolation dielectric layer and a metal layer which are sequentially arranged from bottom to top, wherein the lateral grating layer comprises a plurality of groups of lateral gratings; the plurality of groups of lateral gratings are sequentially arranged along a first direction; the periods of the plurality of groups of lateral gratings are different from each other; each group of lateral gratings comprises a plurality of gratings; the plurality of gratings are arranged along a second direction; and the first direction intersects with the second direction.

2. The semiconductor chip of claim 1, wherein the first direction is a light radiation direction.

3. The semiconductor chip of claim 1, wherein the first direction is vertical to the second direction.

4. The semiconductor chip of claim 1, wherein the periods of each group of lateral gratings are distributed progressively or randomly in the first direction.

5. The semiconductor chip of claim 1, wherein the current isolation dielectric layer and the metal layer are defined to form a current injection region, and the lateral grating layer is arranged in the current injection region.

6. The semiconductor chip of claim 1, wherein
an anti-reflection coating layer is arranged on a light-exiting end face of the semiconductor chip, and a high-reflection coating layer is arranged on a high-reflection end face.

7. The semiconductor chip of claim 1, wherein the periods of the plurality of groups of lateral gratings are respectively as follows:
dᵢ=2w/(m+i);
wherein dᵢ is the period, w is the width of the upper waveguide layer, m is the light mode order, and i is an integer greater than or equal to 1.

8. A preparation method of a high-power semiconductor chip, comprising:
forming in sequence a lower confinement layer, a lower waveguide layer, an active layer, and an upper waveguide layer on the substrate;
forming in sequence a plurality of groups of lateral gratings on the upper waveguide layer along the first direction, wherein the periods of the plurality of groups of lateral gratings are different from each other, a plurality of gratings of each group of lateral gratings are distributed along the second direction, and the first direction intersects with the second direction; and
forming in sequence an upper confinement layer, a contact layer, a current isolation dielectric layer and a metal layer on the plurality of groups of lateral gratings.

9. The preparation method of a semiconductor chip of claim 8, wherein the forming in sequence a plurality of groups of lateral gratings on the upper waveguide layer along the first direction comprises:
forming a lateral grating layer on the upper waveguide layer through epitaxial growth; and
etching on the lateral grating layer to form grating stripes.

10. The semiconductor chip of claim 2, wherein the first direction is vertical to the second direction.
